(19) United States
(12) Patent Application Publication
(10) Pub. No.: US 2026/0209599 A1
(43) Pub. Date: Jul. 23, 2026

(54) CORE-SHELL QUANTUM DOT AND PREPARATION METHOD THEREFOR AND QUANTUM DOT ELECTROLUMINESCENT DEVICE

(71) Applicant: Guangdong Juhua Research Institute of Advanced Display, Guangzhou, Guangdong (CN)

(72) Inventor: Tianfeng WANG, Guangzhou, Guangdong (CN)

(73) Assignee: Guangdong Juhua Research Institute of Advanced Display, Guangzhou, Guangdong (CN)

(21) Appl. No.: 19/142,631

(22) PCT Filed: Sep. 21, 2023
(86) PCT No.: PCT/CN2023/120369

§ 371 Date: Jun. 23, 2025

(30) Foreign Application Priority Data
Dec. 26, 2022 (CN) 202211679613.3

(51) Int. Cl. C09K 11/88; B82Y 20/00; B82Y 40/00; H10K 50/115; H10K 102/00

(52) U.S. Cl. CPC C09K 11/883; B82Y 20/00; B82Y 40/00; H10K 50/115; H10K 2102/321

(57) ABSTRACT

A core-shell quantum dot and a preparation method therefor, and a quantum-dot electroluminescent device. The core-shell quantum dot includes a seed crystal, a core layer covering a surface of the seed crystal, and a shell layer covering the core layer. Compared with a core-shell quantum dot in the prior art, a seed crystal is introduced in the structure of a core-shell quantum dot, a core layer is first grown on the seed crystal, and then a shell layer covering the core layer is formed, such that the nucleation uniformity of the core layer is improved, and the luminous efficiency of the quantum dot is improved.

The present disclosure claims priority to the Chinese patent disclosure No. 202211679613.3, filed on Dec. 26, 2022, and entitled “CORE-SHELL QUANTUM DOT AND PREPARATION METHOD THEREFOR AND QUANTUM DOT ELECTROLUMINESCENT DEVICE”, the content of which is incorporated herein by reference in its entirety.

### TECHNICAL FIELD

The present disclosure relates to a field of display, in particular to a core-shell quantum dot and a preparation method therefor, and a quantum dot electroluminescent device.

### BACKGROUND

Quantum dot electroluminescent devices have the advantages of high color gamut, self-luminescence, low turn-on voltage, fast response speed and the like, can be used in various display devices such as mobile phones, computers and televisions, and have a broad development prospect. At present, quantum dots in a quantum dot electroluminescent device are usually prepared by a hot-injection method. In this method, a core is first formed through hot injection, and after ripening, a shell is added to obtain a complete quantum dot.

### Technical Problem

In this method, a nucleation reaction is fast and is greatly affected by the injection environment, resulting in poor size uniformity and high rigidity of the core formed. Large interface stress defects with a subsequent shell are generated, thereby affecting the luminous efficiency and stability of the quantum dots.

### Technical Solution

The present disclosure provides a core-shell quantum dot and a preparation method therefor, and a quantum dot electroluminescent device, to solve the problem of poor uniformity of quantum dot cores in the existing core-shell quantum dots.

To solve the above problem, the technical solution provided by the present disclosure is as follows.

The present disclosure provides a core-shell quantum dot, including:
a seed crystal;
a core layer covering the seed crystal, serving as a quantum dot core; and
a shell layer covering the quantum dot core.

In some embodiments of the present disclosure, an average particle size of the seed crystal is 1 nanometers to 5 nanometers; and/or the seed crystal includes one or more of a carbon quantum dot, a silicon quantum dot, and a carbon-silicon quantum dot.

In some embodiments of the present disclosure, the average particle size of the seed crystal is greater than or equal to 0.1 times and less than or equal to 0.6 times an average particle size of the quantum dot core.

In some embodiments of the present disclosure, the average particle size of the quantum dot core is 2 nanometers to 10 nanometers.

In some embodiments of the present disclosure, an average particle size of the core-shell quantum dot is 6 nanometers to 20 nanometers.

In some embodiments of the present disclosure, a surface of the seed crystal is connected with hydroxyl ligands and/or carboxyl ligands.

In some embodiments of the present disclosure, an absorption edge of the seed crystal is smaller than an emission wavelength of the core layer.

In some embodiments of the present disclosure, the surface of the seed crystal is connected with an ion same as a cation of the core layer, and/or the surface of the seed crystal is connected with an ion same as an anion of the core layer.

In some embodiments of the present disclosure, a material of the core layer and a material of the shell layer of the core-shell quantum dot are independently selected from one or more of a group II-VI compound, a group III-V compound, a group IV-VI compound, or a group I-III-VI compound, wherein the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe or HgZnSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs or InAlPSb, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe or SnPbSTe, and the group I-III-VI compound is selected from one or more of CuInS, CuInSe, or AgInS.

The present disclosure also provides a method for preparing a core-shell quantum dot, including:
providing a seed crystal;
dispersing the seed crystal in a core reaction system including a first cation precursor;
adding an anion precursor to grow a quantum dot core under an inert gas environment at a first preset temperature; and
adding a shell precursor for a ripening treatment to obtain a core-shell quantum dot mixed solution;
performing precipitation treatment on the core-shell quantum dot mixed solution to obtain the core-shell quantum dot;
wherein the seed crystal includes one or more of a carbon quantum dot, a silicon quantum dot, and a carbon-silicon quantum dot.

In some embodiments of the present disclosure, an average particle size of the seed crystal is 1 nm to 5 nm.

In some embodiments of the present disclosure, the average particle size of the seed crystal is greater than or equal to 0.1 times and less than or equal to 0.6 times an average particle size of the quantum dot core.

In some embodiments of the present disclosure, the average particle size of the quantum dot core is 2 nm to 10 nm.

In some embodiments of the present disclosure, an average particle size of the core-shell quantum dot is 6 nm to 20 nm.

In some embodiments of the present disclosure, the anion precursor includes one or more of S—OAm, S—OA, S-ODE, S-TOP, S-TBP, S-DPP, TMS, Se—OAm, Se—OA, Se-ODE, Se-TOP, Se-TBP, Se-DPP, Te-TOP, and Te-TBP.

In some embodiments of the present disclosure, the shell precursor includes a shell anion precursor including one or more of S—OAm, S—OA, S-ODE, S-TOP, S-TBP, S-DPP, TMS, Se—OAm, Se—OA, Se-ODE, Se-TOP, Se-TBP, Se-DPP, Te-TOP, and Te-TBP.

In some embodiments of the present disclosure, the first preset temperature is 200° C. to 300° C.

In some embodiments of the present disclosure, the step of preparing the quantum dot core further includes adding a second cation precursor different from the first cation precursor for growth.

In some embodiments of the present disclosure, the first cation precursor and the second cation precursor include one or more of a zinc precursor, an indium precursor, a cadmium precursor, a mercury precursor, a gallium precursor, an aluminum precursor, a tin precursor, a lead precursor, a copper precursor, and a silver precursor.

The present disclosure also provides a quantum dot electroluminescent device, including an anode, a cathode, and a quantum dot light-emitting layer between the anode and the cathode, wherein a material of the quantum dot light-emitting layer includes the core-shell quantum dot according to any of the above embodiments.

### Beneficial Effects

The present disclosure provides a core-shell quantum dot, including a seed crystal, a core grown on a surface of the seed crystal, and a shell layer covering the core. Compared with the prior art, the seed crystal is introduced into the structure of the core-shell quantum dot, the core layer is first grown on the seed crystal, and then the shell layer is formed to coat the core layer, so that the nucleation uniformity of the core layer is improved, and luminous efficiency of the quantum dot is improved.

### BRIEF DESCRIPTION OF DRAWINGS

In order to more clearly illustrate the technical solutions in some embodiments of the present disclosure, the following will briefly introduce the drawings required in the embodiment description. Obviously, the drawings in the following description merely represent some of the embodiments of the present disclosure, and other drawings may be obtained by those skilled in the art without creative efforts

FIG. 1 is a flow chart of a method for preparing a core-shell quantum dot according to an embodiment of the present disclosure;

FIG. 2 is an upright quantum dot electroluminescent device according to an embodiment of the present disclosure;

FIG. 3 is an inverted quantum dot electroluminescent device according to an embodiment of the present disclosure;

FIG. 4 is a particle size distribution curve of a core-shell quantum dot according to an embodiment of the present disclosure.

### EMBODIMENTS OF THE PRESENT DISCLOSURE

In the description of the present disclosure, it needs to be understood that “and/or” describes the association relationship of the associated objects, which means that there can be three kinds of relationships, for example, A and/or B can mean that A exists alone, A and B exist simultaneously, and B exists alone. Wherein A and B can be singular or plural.

In the present disclosure, “at least one” means one or more, and “a plurality of” means two or more. “One or more”, “at least one of the following” or the like means any combination of these items, including any combination of single item or multiple items. For example, “at least one of a, b, or c”, or “at least one of a, b, and c” can mean a, b, c, a-b (i.e. a and b), a-c, b-c, or a-b-c, wherein a, b, and c can be single or multiple.

In the present disclosure, in forming another layer “on” a certain layer, the so-called “on” is a broad concept, which can mean that the formed another layer is adjacent to the certain layer, or can mean that there is another spacing structure layer between the another layer and the certain layer, for example, forming a top electrode “on” a first carrier functional layer, the so-called “on” can mean that the formed top electrode is adjacent to the first carrier functional layer, or can mean that there is another spacing structure layer, for example, “light-emitting layer”, between the top electrode and the first carrier functional layer.

The present disclosure provides a core-shell quantum dot, including a seed crystal, a core layer covering the seed crystal, and a shell layer covering the core layer. Compared with the prior art, the seed crystal is introduced into the structure of the core-shell quantum dot, the core layer is first grown on the seed crystal, and then the shell layer is formed to coat the core layer, so that the nucleation uniformity of the core layer is improved, and luminous efficiency of the quantum dot is improved.

In some embodiments, an average particle size of the seed crystal is 1 nanometers to 5 nanometers. Specifically, the average particle size may be 1 nm, 2 nm, 3 nm, 4 nm, or 5 nm. The size of the seed crystal should not be too large, and a large difference in size distribution may lead to a large difference in crystal surface activity, thereby affecting the subsequent epitaxial growth of a light-emitting material.

In some embodiments, a surface of the seed crystal is connected with hydroxyl ligands and/or carboxyl ligands, which may make the seed crystal better dispersed in a solvent and avoid agglomeration of the seed crystal.

In some embodiments, an absorption edge of the seed crystal is smaller than an emission wavelength of the core, i.e., a band gap of the seed crystal is larger than that of the core, so as to ensure that the seed crystal does not emit light and the core emits light.

In some embodiments, the surface of the seed crystal is connected with an ion same as a cation of the core layer, and/or the surface of the seed crystal is connected with an ion same as an anion of the core layer. By connecting the same cations and/or anions as the core layer on the surface of the seed crystal, the growth of the subsequent core layer on the surface of the seed crystal is facilitated, and the lattice mismatch between the seed crystal and the light-emitting material is reduced.

In some embodiments, the seed crystal includes, but is not limited to, one or more of a carbon quantum dot, a silicon quantum dot, and a carbon-silicon quantum dot. The carbon quantum dot, the silicon quantum dot, and the carbon-silicon quantum dot have a mature synthesis process, uniform size, good stability, large band gap, good dispersibility in a solvent, and poor agglomeration, and have good epitaxy with the subsequent light-emitting material, thereby improving the uniformity of the core nucleation. Meanwhile, the carbon quantum dot, the silicon quantum dot, and the carbon-silicon quantum dot have low stress, thereby reducing the stress of the subsequent growth of the core and the shell layer, reducing lattice defects, and improving luminous efficiency and stability of the quantum dots. In specific embodiments of the present disclosure, the carbon quantum dot may be selected as the seed crystal.

The seed crystal and the core layer form a quantum dot core, and the shell layer coats the quantum dot core. The average particle size of the seed crystal is greater than or equal to 0.1 times and less than or equal to 0.6 times an average particle size of the quantum dot core, specifically 0.2 times, 0.3 times, 0.4 times, 0.5 times, etc. By controlling the ratio of the seed crystal and the core within this range, the seed crystal is prevented from being too large, the core is prevented from being too thin, and the surface of the core is prevented from having many defects.

In some embodiments, the average particle size of the quantum dot core is 2-10 nm. Specifically, the average particle size may be 2.3 nm, 2.7 nm, 3.3 nm, 4.5 nm, 6 nm, 7 nm, 9 nm, or 10 nm, etc.

In some embodiments, an average particle size of the core-shell quantum dot is 6-20 nm. Specifically, the average particle size may be 6 nm, 8 nm, 10 nm, 15 nm, 16 nm, 19 nm, or 20 nm.

A material of the core layer of the core-shell quantum dot and a material of the shell layer are independently selected from one or more of a group II-VI compound, a group III-V compound, a group IV-VI compound, or a group I-III-VI compound. The group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe or HgZnSTe, the group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs or InAlPSb, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe or SnPbSTe, and the I-III-VI compound is selected from one or more of CuInS, CuInSe, or AgInS.

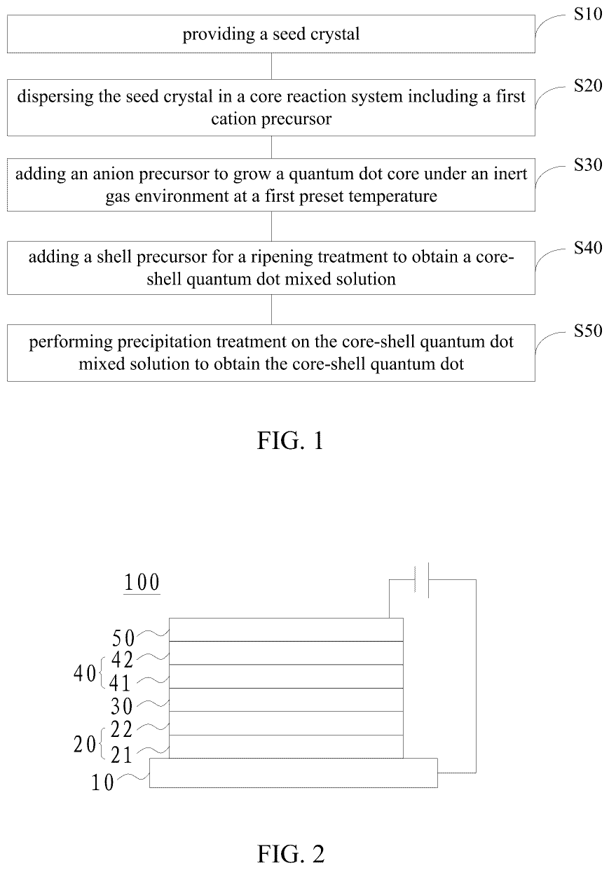

As shown in FIG. 1, the present disclosure also provides a method for preparing a core-shell quantum dot, including the following steps: S10, providing a seed crystal; S20, dispersing the seed crystal in a core reaction system including a first cation precursor; S30, adding an anion precursor to grow a quantum dot core under an inert gas environment at a first preset temperature; S40, adding a shell precursor for a ripening treatment to obtain a core-shell quantum dot mixed solution; and S50, performing precipitation treatment on the core-shell quantum dot mixed solution to obtain the core-shell quantum dot.

In S20, the core reaction system includes one or more of oleic acid and oleylamine. The first cation precursor is a core cation precursor, i.e., a cation precursor used for nucleation.

Specifically, in some embodiments, the core reaction system may be a solution of the first cation precursor.

In S20, the seed crystal is mixed with the core reaction system, stirred at a second preset temperature in an inert gas atmosphere, and then vacuumized. The second preset temperature is 80-120° C., and may be specifically 80° C., 90° C., 100° C., 110° C. or 120° C. The stirring time is 10-60 minutes, and may be specifically 10 minutes, 20 minutes, 30 minutes, 40 minutes, 50 minutes or 60 minutes. The vacuumizing time is 10-60 minutes, and may be specifically 10 minutes, 20 minutes, 30 minutes, 40 minutes, 50 minutes or 60 minutes.

In S30, the first preset temperature is a temperature required for nucleation reaction, and the first preset temperature is 200-300° C., and may be specifically 200° C., 220° C., 250° C., 270° C., 280° C. or 300° C.

In S30, the anion precursor is a core anion precursor, i.e., an anion precursor used for nucleation.

In S30, the step of preparing the quantum dot core further includes adding a second cation precursor different from the first cation precursor for growth.

Specifically, the second cation precursor and the anion precursor may be added into the core reaction system in sequence and alternately for multiple times, and the second cation precursor and the anion precursor grow on the seed crystal to form a core layer. In other embodiments, one precursor may be added first, and then the other precursor may be added, for example, the second cation precursor is added first, and then the anion precursor is added.

The first cation precursor and the second cation precursor include one or more of a zinc precursor, an indium precursor, a cadmium precursor, a mercury precursor, a gallium precursor, an aluminum precursor, a tin precursor, a lead precursor, a copper precursor and a silver precursor. For example, the first cation precursor may be the zinc precursor, and the second cation precursor may be the cadmium precursor.

The anion precursor includes one or more of S—OAm, S—OA, S-ODE, S-TOP, S-TBP, S-DPP, TMS, Se—OAm, Se—OA, Se-ODE, Se-TOP, Se-TBP, Se-DPP, TeTOP and Te-TBP. For example, the anion precursor may be Se-TOP.

In S40, the shell precursor includes a shell anion precursor, and a time of the ripening treatment is 20-30 minutes, and may be specifically 20 minutes, 25 minutes or 30 minutes. After the ripening treatment, a shell layer is obtained.

The shell anion precursors include one or more of S—OAm, S—OA, S-ODE, S-TOP, S-TBP, S-DPP, TMS, Se—OAm, Se—OA, Se-ODE, Se-TOP, Se-TBP, Se-DPP, TeTOP, and Te-TBP.

In some embodiments, different anion precursors may be added in multiple times for a ripening treatment to obtain a multilayer shell layers. For example, S41, Se-TOP is added, and a ripening treatment is performed for 30 minutes to obtain a ZnSe shell; and S42, S-TOP is added, and a ripening treatment is performed for 30 minutes to obtain a ZnS shell.

S50, the core-shell quantum dot mixed solution prepared in S40 is subjected to precipitation treatment, and the obtained precipitate is the core-shell quantum dot prepared in the present disclosure.

In the preparation of a quantum dot layer by using the core-shell quantum dots, the prepared core-shell quantum dots may be dissolved in n-octane to obtain a core-shell quantum dot solution.

The present disclosure also provides a quantum dot electroluminescent device 100, including an anode 10, a cathode 50, and a quantum dot light-emitting layer 30 between the anode 10 and the cathode 50, where a material of the quantum dot light-emitting layer 30 includes the core-shell quantum dot according to any of the preceding embodiments or the core-shell quantum dot prepared by the method according to any of the preceding embodiments.

The quantum dot electroluminescent device may be an upright-type quantum dot electroluminescent device or an inverted-type quantum dot electroluminescent device.

Specifically, as shown in FIG. 2, the upright-type quantum dot electroluminescent device includes an anode 10, a hole functional layer 20 disposed on the anode 10, a quantum dot light-emitting layer 30 disposed on the hole functional layer 20, an electron functional layer 40 disposed on the quantum dot light-emitting layer 30, and a cathode 50 disposed on the electron functional layer 40.

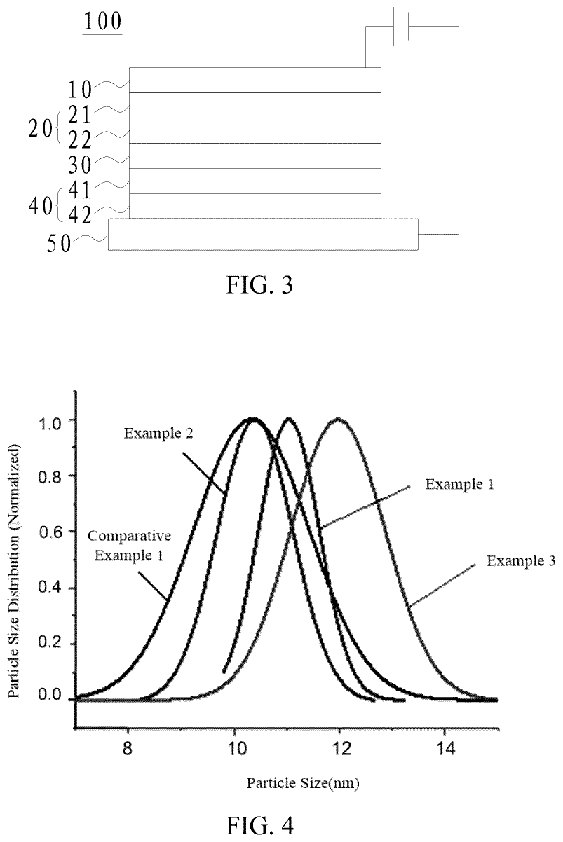

As shown in FIG. 3, the inverted-type quantum dot electroluminescent device includes a cathode 50, an electron functional layer 40 disposed on the cathode 50, a quantum dot light-emitting layer 30 disposed on the electron functional layer 40, a hole functional layer 20 disposed on the quantum dot light-emitting layer 30, and an anode 10 disposed on the hole functional layer 20.

The anode 10 and the cathode 50 may be anodes and cathodes known in the art for light-emitting devices, for example, may be independently selected from, but not limited to, a doped metal oxide electrode, a composite electrode of metal and metal oxide, a graphene electrode, a carbon nanotube electrode, a metal electrode or an alloy electrode, respectively. A material of the doped metal oxide may be selected from, but not limited to, one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), and aluminum-doped magnesium oxide (AMO). The composite electrode is a composite electrode with metal sandwiched between doped or undoped transparent metal oxide particles, such as AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, and the like. A material of the metal electrode may be selected from, but not limited to, one or more of Ag, Al, Cu, Mo, Au, Pt, Si, Ca, Mg, and Ba. Herein, “/” represents a stacked structure, for example, AZO/Ag/AZO represents a composite electrode including an AZO layer, an Ag layer, and an AZO layer stacked in this order.

In some embodiments, the hole functional layer 20 may include a hole transport layer 22. In other embodiments, the hole functional layer 20 may further include a hole injection layer 21 disposed in a stack with the hole transport layer 22, the hole transport layer 22 disposed adjacent to the quantum dot light-emitting layer 30, and the hole injection layer 21 disposed adjacent to the anode 10.

In some embodiments, the electron functional layer 40 may include an electron transport layer 41. In other embodiments, the electron functional layer 40 may further include an electron injection layer 42 disposed in a stack with the electron transport layer 41, the electron transport layer 41 disposed adjacent to the quantum dot light-emitting layer 30, and the electron injection layer 42 disposed adjacent to the cathode 50.

A material of the electron transport layer 41 may be a material known in the art for the electron transport layer, for example, may be selected from, but not limited to, one or more of a metal oxide, a doped metal oxide, a group II-VI semiconductor material, a group III-V semiconductor material, and a group I-III-VI semiconductor material. Specifically, the metal oxides may be selected from, but not limited to, one or more of ZnO, BaO, TiO₂, SnO₂, and the like. A metal oxide in the doped metal oxide may be selected from, but not limited to, one or more of ZnO, TiO₂, SnO₂, and the like, and a doping element in the doped metal oxide may be selected from, but not limited to, one or more of Al, Mg, Li, In, Ga, and the like. As an example, the doped metal oxide may be aluminum zinc oxide (AZO), lithium-doped zinc oxide (LZO), magnesium-doped zinc oxide (MZO), and the like. The group II-VI semiconductor material may be selected from, but not limited to, one or more of ZnS, ZnSe, CdS, and the like. The group III-V semiconductor material may be selected from, but not limited to, one or more of InP, GaP, and the like. The group I-III-VI semiconductor material may be selected from, but not limited to, one or more of CuInS, CuGaS, and the like.

A material of the electron injection layer 42 may be selected from, but not limited to, one or more of cesium carbonate, cesium fluoride, cesium azide, and lithium fluoride.

A material of the hole transport layer 22 may be a material known in the art for the hole transport layer 22, for example, may be selected from, but not limited to, one or more of 4,4′-N,N′-dicarbazolyl-biphenyl (CBP), N,N′-diphenyl-N,N′-bis(1-naphthyl)-1,1′-biphenyl-4,4′-diamine (a-NPD), N,N′-diphenyl-N,N′-bis(3-methylphenyl)-(1,1′-biphenyl)-4,4′-diamine (TPD), N,N′-bis(3-methylphenyl)-N,N′-bis(phenyl)-spiro(spiro-TPD), N,N′-di(4-(N,N′-diphenyl-amino)phenyl)-N,N′-diphenylbenzidine (DNTPD), 4,4′,4′-tris(carbazol-9-yl)-triphenylamine (TCTA), 4,4′,4′-tris(N-3-methylphenyl-N-phenylamino)triphenylamine (m-MTDATA), poly[(9,9′-dioctylfluorenyl-2,7-diyl)-co-(4,4′-(N-(4-sec-butyphenyl)diphenylamine))] (TFB), poly[N,N′-bis(4-butylphenyl)-N,N′-bis(phenyl)-benzi (poly-TPD), polyaniline, polypyrrole, poly(p) phenylenevinylene, poly(phenylenevinylene) (PPV), Poly[2-methoxy-5-(2-ethylhexyloxy)phenylenevinylene-1,4-diyl] (MEH-PPV) and poly[2-methoxy-5-(3′,7′-dimethyloctyloxy)-1,4-phenylenevinylene] (MOMO-PPV), copper phthalocyanine, aromatic tertiary amines, polynuclear aromatic tertiary amines, 4,4′-bis(carbazol-9-yl)-1,1′-biphenyl, N,N,N′,N′-tetraarylbiphenylamines, PEDOT:PSS and derivatives thereof, poly(N-vinylcarbazole) (PVK) and derivatives thereof, polymethacrylate and derivatives thereof, poly(9,9-di-n-octylfluorenyl-2,7-diyl) and derivatives thereof, poly(spirofluorene) and derivatives thereof, N,N′-di(naphthalen-1-yl)-N,N′-diphenylbenzidine (NPB), spiro-NPB, doped graphene, non-doped graphene, C60, doped or non-doped NiO, doped or non-doped MoO₃, doped or non-doped WO₃, doped or non-doped V₂O₅, doped or non-doped P-type gallium nitride, doped or non-doped CrO₃, and doped or non-doped CuO.

A material of the hole injection layer 21 may be a material known in the art for the hole injection layer 21, for example may be selected from, but not limited to, one or more of 2,3,6,7,10,11-hexacyano-1,4,5,8,9,12-hexaazatriphenylene (HAT-CN), PEDOT, PEDOT:PSS, a derivative of PEDOT:PSS doped with s-MoO₃ (PEDOT:PSS:s-MoO₃), 4,4′,4′-tris(N-3-methylphenyl-N-phenylamino)triphenylamine (m-MTDATA), tetracyanoquinodimethane (F4-TCQN), copper phthalocyanine, nickel oxide, molybdenum oxide, tungsten oxide, vanadium oxide, molybdenum sulfide, tungsten sulfide, and copper oxide.

The quantum dot light-emitting layer 30 of the quantum dot electroluminescent device provided by the present disclosure includes the core-shell quantum dots, the seed crystal particle size of the core-shell quantum dots is uniform, so that subsequent quantum dot growth is more uniform, the seed crystal particles may effectively reduce the stress inside the quantum dots and reduce lattice defects, so that the fluorescence efficiency of the device is higher, and the stability of the device is improved.

The present disclosure is described in detail below by means of specific examples. The following examples are only part of the examples of the present disclosure and are not intended to limit the present disclosure.

### Example 1

Preparation of a zinc precursor: 5 mmol of zinc acetate was mixed with a mixed solvent of 5 mL oleic acid and 10 mL octadecene. Then, heating was performed at 10 Pa. Here, the heating temperature was 100° C. and the heating time was 10 minutes. Subsequently, the temperature was raised to 200° C. in an inert gas atmosphere to perform heating. Wherein, the heating time is 30 minutes to obtain the zinc precursor.

Preparation of a cadmium precursor: 2 mmol of cadmium oxide was dissolved in a mixed solvent of 2 mL oleic acid and 8 mL octadecene. Then heating was performed at 10 Pa. Here, the heating temperature was 100° C., and the heating time was 10 minutes. Subsequently, the temperature was raised to 200° C. in an inert gas atmosphere to perform heating. Wherein, the heating time is 30 minutes to obtain the cadmium precursor.

Dispersion of a seed crystal: under normal temperature and an inert gas atmosphere, a carbon quantum dot solution was mixed with the zinc precursor, the carbon quantum dot solution including carbon quantum dots and ethanol, a molar amount of the carbon quantum dots being 0.3 mmol, and an average particle size being 2 nm. Then the temperature was gradually raised to 120° C. within 30 minutes, so that the carbon quantum dots were completely dissolved in the zinc precursor.

Preparation of a core layer: the temperature was raised to 300° C., and 1 mmol of Se-TOP and 0.1 mmol of the cadmium precursor were gradually added within 10 minutes, and then the ripening reaction was carried out for 30 minutes to obtain the ZnCdSe core layer.

Preparation of a shell layer: 1 mmol of Se-TOP was injected and then subjected to a ripening treatment for 30 minutes to form a ZnSe shell. Subsequently, 1 mmol of S-TOP was injected and ripened for another 30 minutes to form a ZnS shell layer. The resulting solution is a mixed solution of core-shell quantum dots.

The core-shell quantum dot solution was obtained by precipitating the core-shell quantum dot mixed solution to obtain a precipitate and dissolving the precipitate in n-octane solution.

### Example 2

This Example is different from Example 1 in that the molar amount and size of the added carbon quantum dots are different from those of Example 1, and the molar amount of the added carbon quantum dots in this Example is 0.04 mmol, and the average particle size is 1 nm.

### Example 3

This Example is different from Example 1 in that the molar amount and size of the added carbon quantum dots are different from those of Example 1, and the molar amount of the added carbon quantum dots in this Example is 1 mmol, and the average particle size is 5 nm.

### Comparative Example 1

Preparation of a zinc precursor: 5 mmol of zinc acetate was mixed with a mixed solvent of 5 mL oleic acid and 10 mL octadecene. Then, heating was performed at 10 Pa. Here, the heating temperature was 100° C. and the heating time was 10 minutes. Subsequently, the temperature was raised to 200° C. in an inert gas atmosphere to perform heating. Wherein, the heating time is 30 minutes to obtain the zinc precursor.

Preparation of a cadmium precursor: 2 mmol of cadmium oxide was dissolved in a mixed solvent of 2 mL oleic acid and 8 mL octadecene. Then heating was performed at 10 Pa. Here, the heating temperature was 100° C., and the heating time was 10 minutes. Subsequently, the temperature was raised to 200° C. in an inert gas atmosphere to perform heating. Wherein, the heating time is 30 minutes to obtain the cadmium precursor.

Preparation of a core layer: under an inert gas atmosphere, the zinc precursor was heated to 300° C., and 1 mmol of Se-TOP was added and then a ripening reaction was carried out for 1 minutes. Subsequently, 0.1 mmol of the cadmium precursor was added and then a ripening reaction was carried out for 30 minutes to obtain the ZnCdSe core layer.

Preparation of a shell layer: 1 mmol of Se-TOP was injected and then subjected to a ripening treatment for 30 minutes to form a ZnSe shell. Subsequently, 1 mmol of S-TOP was injected and ripened for another 30 minutes to form a ZnS shell layer. The resulting solution is a mixed solution of core-shell quantum dots.

The core-shell quantum dot solution was obtained by precipitating the core-shell quantum dot mixed solution to obtain a precipitate and dissolving the precipitate in n-octane solution.

The particle size distribution of the core-shell quantum dots of Examples 1 to 3 and the particle size distribution of the core-shell quantum dots of Comparative Example 1 were detected by using a transmission electron microscope (TEM), and the detection result is shown in FIG. 4, which is a particle size distribution fitting normalized curve diagram of the core-shell quantum dots synthesized in different Examples.

As shown in FIG. 4, the full width at half maximum of the particle size distribution of Example 1 is 1.35 nm, the full width at half maximum of the particle size distribution of Example 2 is 1.67 nm, the full width at half maximum of the particle size distribution of Example 3 is 2.10 nm, and the full width at half maximum of the particle size distribution of Comparative Example 1 is 2.58 nm. It can be seen that the full width at half maximum of the particle size distribution of the core-shell quantum dots provided by the present disclosure is narrower, and the size of the core-shell quantum dots is more uniform. The possible reason is that the introduction of the seed crystal with uniform size makes the quantum dots grown on the seed crystal subsequently more uniform.

### Device Example 1

Preparation of an anode 10: a substrate was provided, and an anode 10 was formed on the substrate. The substrate was a glass substrate with a thickness of 0.4 mm, and a material of anode 10 was indium tin oxide (ITO) with a thickness of 50 nm.

Cleaning of the anode 10: the anode 10 was cleaned by ultrasonic cleaning with an alkaline cleaning solution (preferably with a PH value greater than 12) for 15 minutes. It was then ultrasonically cleaned twice with deionized water, each time for 15 minutes, followed by ultrasonic cleaning with isopropanol for 15 minutes to remove surface impurities. Afterward, it was dried at 80° C. for 2 hours and finally treated with ozone UV for 15 minutes.

Preparation of a hole injection layer 21: a PEDOT:PSS aqueous solution was spin-coated on the anode 10, and annealing treatment was performed to obtain the hole injection layer 21 with a thickness of 20 nm. The molar ratio of PEDOT and PSS was 1:1, the spin-coating speed was 5000 rpm, the spin-coating time was 40 s, the annealing temperature was 150° C., and the annealing time was 15 minutes.

Preparation of a hole transport layer 22: in a glove box (the water and oxygen contents are less than 0.1 ppm), a TFB solution was spin-coated on the hole injection layer 21, and annealing treatment was performed to obtain the hole transport layer 22 with a thickness of 20 nm. The TFB concentration was 8 mg/mL, the solvent in the TFB solution was chlorobenzene, the spin-coating speed was 3000 rpm, the annealing temperature was 150° C., and the annealing time was 30 minutes.

Preparation of a quantum dot light-emitting layer 30: in a glove box (the water and oxygen contents are less than 0.1 ppm), the core-shell quantum dot solution in Example 1 was spin-coated on the hole transport layer 22 to form the quantum dot light-emitting layer 30 with a thickness of 20 nm. The concentration of the core-shell quantum dot was 30 mg/mL.

Preparation of an electron transport layer 41: in a glove box (the water and oxygen contents are less than 0.1 ppm), an ethanol solution with a ZnO concentration of 30 mg/mL was spin-coated on the quantum dot light-emitting layer 30, and annealing treatment was performed to form the electron transport layer 41 with a thickness of 50 nm. The spin-coating speed was 3000 rpm, the spin-coating time was 40 s, the annealing temperature was 80° C., and the annealing time was 30 minutes.

Preparation of a cathode 50: Ag was evaporated on the electron transport layer 41 to form the cathode 50 with a thickness of 100 nm.

Device packaging: the device was packaged with epoxy resin glue and a cover glass.

### Device Example 2

The Device Example 2 is prepared in the same manner as the Device Example 1, except that the material of the quantum dot light-emitting layer 30 of the Device Example 2 was the core-shell quantum dot solution prepared in the Example 2.

### Device Example 3

The Device Example 3 is prepared in the same manner as the Device Example 1, except that the material of the quantum dot light-emitting layer 30 of the Device Example 3 was the core-shell quantum dot solution prepared in the Example 3.

### Device Comparative Example 1

The Device Comparative Example 1 is prepared in the same manner as the Device Example 1, except that the material of the quantum dot light-emitting layer 30 of the Device Comparative Example 1 was the core-shell quantum dot solution prepared in the Comparative Example 1.

The fluorescence efficiency (QY) of the quantum dots, the device luminous efficiency (EQE), and the device lifetime of the light-emitting devices of the Device Examples 1-3 and the light-emitting device of the Device Comparative Example 1 were detected, and the detection results were shown in Table 1. Among them, T95@1knit refers to the time experienced by the initial brightness of the device to decay to 95%, and the aging time under 1000 nit is converted.

The test method of the fluorescence efficiency (QY) and the luminous efficiency (EQE) is as follows: the efficiency test system built by the Lab View controlled QE PRO spectrometer, the Keithley 2400, and the Keithley 6485 is used to measure the parameters such as voltage, current, brightness, and light-emitting spectrum by using the FISFA FPD optical property measuring equipment, and the fluorescence efficiency (QY) and the luminous efficiency EQE are obtained by calculation.

| | Fluorescence | Device luminous | T95@1knit |
|---|---|---|---|
| Device | efficiency (QY) | efficiency (EQE) | (h) |
| Example 1 | 66% | 17% | 126 |
| Example 2 | 51% | 16% | 89 |
| Example 3 | 41% | 13% | 36 |
| Comparative | 36% | 11% | 23 |
| Example 1 | | | |

As can be seen from Table 1, compared with the light-emitting device of the Device Comparative Example 1, the light-emitting devices of the Device Examples 1-3 have higher fluorescence efficiency, higher luminous efficiency, and higher lifetime. It can be seen that the core-shell quantum dots provided by the present disclosure are used in the quantum dot light-emitting layer of the light-emitting device, and have the effect of improving the luminous efficiency and the lifetime of the light-emitting device. The reason can be that the seed crystals of the core-shell quantum dots in the quantum dot light-emitting layer of the light-emitting devices of the Device Examples 1-3 can improve the uniformity of quantum dot nucleation, reduce the stress inside the quantum dots, thereby reducing the lattice defects, and thereby improving the light-emitting stability of the device.

A core-shell quantum dot and a preparation method therefor, and a quantum dot electroluminescent device are described in detail above. The principle and implementation mode of the present disclosure are described by using specific examples. The above description of the embodiments is only used to help understand the technical scheme and the core idea of the present disclosure. It should be understood by those skilled in the art that the technical scheme recorded in the foregoing embodiments can still be modified, or part of the technical features can be replaced equivalently. These modifications or replacements do not make the essence of the corresponding technical scheme deviate from the scope of the technical scheme of the embodiments of the present disclosure.

1. A core-shell quantum dot, comprising:
a seed crystal;
a core layer covering the seed crystal, serving as a quantum dot core; and
a shell layer covering the quantum dot core.

2. The core-shell quantum dot according to claim 1, wherein an average particle size of the seed crystal is 1 nanometers to 5 nanometers; and/or
the seed crystal comprises one or more of a carbon quantum dot, a silicon quantum dot, and a carbon-silicon quantum dot.

3. The core-shell quantum dot according to claim 1, wherein the average particle size of the seed crystal ranges from 0.1 times to 0.6 times an average particle size of the quantum dot core.

4. The core-shell quantum dot according to claim 3, wherein the average particle size of the quantum dot core is 2 nanometers to 10 nanometers.

5. The core-shell quantum dot according to claim 3, wherein an average particle size of the core-shell quantum dot is 6 nanometers to 20 nanometers.

6. The core-shell quantum dot according to claim 1, wherein a surface of the seed crystal is connected with one or both of hydroxyl ligands and/or carboxyl ligands.

7. The core-shell quantum dot according to claim 1, wherein an absorption edge of the seed crystal is smaller than an emission wavelength of the core layer.

8. The core-shell quantum dot according to claim 1, wherein the surface of the seed crystal is connected with an ion same as a cation of the core layer, and/or the surface of the seed crystal is connected with an ion same as an anion of the core layer.

9. The core-shell quantum dot according to claim 1, wherein a material of the core layer and a material of the shell layer of the core-shell quantum dot are independently selected from one or more of a group II-VI compound, a group III-V compound, a group IV-VI compound, or a group I-III-VI compound, wherein the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe er and HgZnSTe, the group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs er and InAlPSb, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe or SnPbSTe, and the group I-III-VI compound is selected from one or more of CuInS, CuInSe, and AgInS.

10. A method for preparing a core-shell quantum dot, comprising:
providing a seed crystal;
dispersing the seed crystal in a core reaction system comprising a first cation precursor;
adding an anion precursor to grow a quantum dot core under an inert gas environment at a first preset temperature;
adding a shell precursor for a ripening treatment to obtain a core-shell quantum dot mixed solution; and
performing precipitation treatment on the core-shell quantum dot mixed solution to obtain the core-shell quantum dot;
wherein the seed crystal comprises one or more of a carbon quantum dot, a silicon quantum dot, and a carbon-silicon quantum dot.

11. The method according to claim 10, wherein an average particle size of the seed crystal is 1 nm to 5 nm.

12. The method according to claim 10, wherein the average particle size of the seed crystal is greater than or equal to 0.1 times and less than or equal to 0.6 times an average particle size of the quantum dot core.

13. The method according to claim 10, wherein the average particle size of the quantum dot core is 2 nm to 10 nm.

14. The method according to claim 10, wherein an average particle size of the core-shell quantum dot is 6 nm to 20 nm.

15. The method according to claim 10, wherein the anion precursor comprises one or more of S—OAm, S—OA, S-ODE, S-TOP, S-TBP, S-DPP, TMS, Se—OAm, Se—OA, Se-ODE, Se-TOP, Se-TBP, Se-DPP, Te-TOP, and Te-TBP.

16. The method according to claim 10, wherein the shell precursor comprises a shell anion precursor comprising one or more of S—OAm, S—OA, S-ODE, S-TOP, S-TBP, S-DPP, TMS, Se—OAm, Se—OA, Se-ODE, Se-TOP, Se-TBP, Se-DPP, Te-TOP, and Te-TBP.

17. The method according to claim 10, wherein the first preset temperature is 200° C. to 300° C.

18. The method according to claim 10, wherein the step of preparing the quantum dot core further comprises adding a second cation precursor different from the first cation precursor for growth.

19. The method according to claim 10, wherein the first cation precursor and the second cation precursor comprise one or more of a zinc precursor, an indium precursor, a cadmium precursor, a mercury precursor, a gallium precursor, an aluminum precursor, a tin precursor, a lead precursor, a copper precursor, and a silver precursor.

20. A quantum dot electroluminescent device, comprising an anode, a cathode, and a quantum dot light-emitting layer between the anode and the cathode, wherein a material of the quantum dot light-emitting layer comprises the core-shell quantum dot comprising:
a seed crystal;
a core layer covering the seed crystal, serving as a quantum dot core; and
a shell layer covering the quantum dot core.
